(19) United States
(12) Patent Application Publication
(10) Pub. No.: US 2007/0089667 A1
(43) Pub. Date: Apr. 26, 2007

(54) Method for manufacturing a thermal interface material

(75) Inventor: Bor-Yuan Hsiao, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/432,565

(22) Filed: May 10, 2006

(30) Foreign Application Priority Data
Oct. 20, 2005 (CN) 200510100542.7

(51) Int. Cl. C30B 13/00; C30B 21/04; C30B 28/08

(52) U.S. Cl. 117/47

(57) ABSTRACT

A method for manufacturing a thermal interface material includes the steps of providing filling particles and a base material; forming a mixture by putting the filling particles and the base material into a container, and keeping the base material melt or in liquid state, and pressing a predetermined pressure to the mixture and mixing the mixture uniformly

### TECHNICAL FIELD

The present invention relates to methods for manufacturing thermal interface materials, and more particularly to a mixing method for manufacturing a thermal interface material.

### BACKGROUND

Electronic components such as semiconductor chips are becoming progressively smaller, while at the same time heat dissipation requirements thereof are increasing. Commonly, a thermal interface material is utilized between the electronic component and a heat sink in order to efficiently dissipate heat generated by the electronic component.

A typical thermal interface material is made by diffusing filling particles with a high heat conduction coefficient in a base material, and when the filling particles are mixed uniformly with the base material, the thermal interface material presents good thermal conductivity In order to mix the filling particles and the base material uniformly, a mixer such as a planetary mixer, a double-shaft mixer or etc. is generally employed. For thermal interface materials which the proportions of the filling particles are small, the filling particles and the base material can be mixed uniformly by mixing round for a long time, and the thermal conductivities of the thermal interface materials can be increased along with increasing proportions of the filling particles.

However, when the proportions of the filling particles increase to a certain degree, the thermal conductivities of the thermal interface materials are hard to increase along with increasing proportions of the filling particles. An important reason is probably rest with the longtime and low-efficiency processes of current methods, and this would lead to asymmetrical mix and form aggregations of the filling particles.

What is needed, therefore, a high efficiency method for manufacturing a thermal interface material.

### SUMMARY

In a preferred embodiment, a method for manufacturing a thermal interface material includes the steps of: providing filling particles and a base material; forming a mixture by putting the filling particles and the base material into a container, and keeping the base material melt or in liquid state; and pressing a predetermined pressure to the mixture and mixing the mixture uniformly.

Other advantages and novel features will become more apparent from the following detailed description when taken in conjunction with the accompanying drawings, in which:

### BRIEF DESCRIPTION OF THE DRAWINGS

Many aspects of the present method for manufacturing a thermal interface material can be better understood with reference to the following drawings. The components in the drawings are not necessarily to scale, the emphasis instead being placed upon clearly illustrating the principles of the present method for manufacturing a thermal interface material. Moreover, in the drawings, like reference numerals designate corresponding parts throughout the several views.

FIG. 1 is a schematic view of a mixture in a container in accordance with a preferred embodiment;

FIG. 2 is a schematic view of pressing a predetermined pressure to the mixture and mixing the mixture of FIG 1; and

FIG. 3 is a graph illustrating a relationship of a thermal resistance and mixing time of a typical thermal interface material and the thermal interface material in accordance with the preferred embodiment repsectively.

The exemplifications set out herein illustrate at least one preferred embodiment of the invention, in one form, and such exemplifications are not to be construed as limiting the scope of the invention in any manner.

### DETAILED DESCRIPTION OF PREFERRED EMBODIMENTS

Embodiments of the present invention will now be described in detail below and with reference to the drawings.

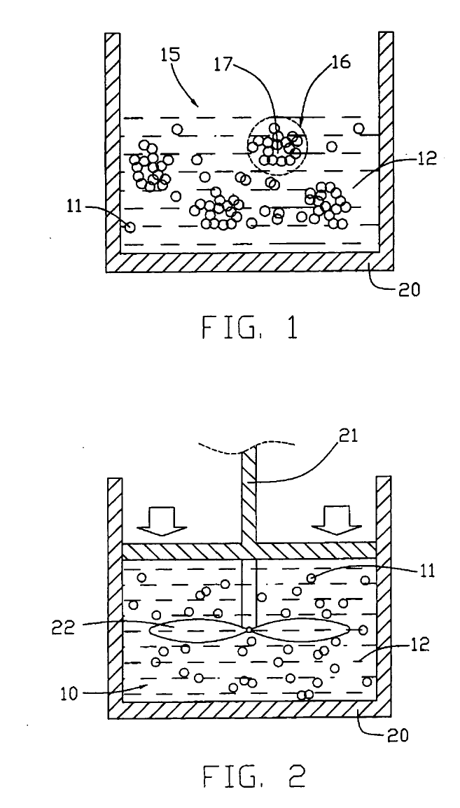

Referring to FIG. 1 and FIG. 2, a method for manufacturing a thermal interface material according to a preferred embodiment is provided. The method comprises the steps of:

1providing filling particles 11 and a base material 12;
forming a mixture 15 by putting the filling particles 11 and the base material 12 into a mixing container 20, and keeping the base material 12 melt or in liquid state; and
pressing and mixing the 15 mixture in the mixing container 20 uniformly

The method for manufacturing a thermal interface material in accordance with the present invention is detail described below and by reference to embodiments.

Providing filling particles 11 and a base material 12. In the preferred embodiment, the filling particles 11 are selected from the group comprising silver (Ag), gold (Au), copper (Cu), nickel (Ni), aluminum (Al), aluminum oxide (Al₂O₃), zinc oxide (ZnO), boron nitride (BN), bauxite, aluminum nitride (AlN), graphite, black carbon, and any suitable combination thereof The base material 12 employs one of a liquid state polymer and a solid state polymer. The liquid state polymer is selected from the group comprising silicone oil, polyethylene glycol, polyester, and any suitable combination thereof. The solid state polymer is selected from the group comprising polyvinyl acetate, polythene (PE), siloxane, polyvinyl chloride (PVC), amino epoxide resin, polyacrylate, polypropylene, epoxide resin, polyformaldehyde, polyacetal, polyvinyl alcohol (PVA), and any suitable combination thereof A ratio by weight of the filling particles 11 to the base material 12 is generally about 1:1 to 9:1. In the preferred embodiment, the filling particles 11 employ 800 grams ZnO particles, and the base material 12 employs 200 grams polyester.

Forming a mixture 15 by putting the filling particles 11 and the base material 12 into a mixing container 20, and keeping the base material 12 melt or in liquid state. The mixing container 20 provides good leak tightness and high pressure endurance. In the mixture 15, the proportion of the filling particles 11 is high, and the filling particles 11 are apt to form aggregations 16 with clearances 17 therein.

Pressing a predetermined pressure to the mixture 15 and mixing the mixture 15 in the mixing container 20 uniformly. In the preferred embodiment, the mixing container 20 is cooperated with a pressure plunge 21 and a mixing rotor 22. In operation, the pressure plunge 21 provides the predetermined pressure to the mixture 15 in the mixing container 20, and the mixing rotor 22 mixes the mixture 15 for a period of time under the predetermined pressure. The predetermined pressure is in the range from 10⁴ newton/m² to 10⁶ newton/m². The mixing time is in the range from 30 minutes to 24 hours. A speed of the mixing rotor 22 is in the range from 5 RPM (Revolution Per Minute) to 100 RPM. In the preferred embodiment, the predetermined pressure is 10⁶ newton/m². The mixing time is 120 minutes, and the speed is 20 RPM. Thereby a thermal interface material 10 is formed. In the interface material 10, the filling particles 11 are dispersed in the base material 12 uniformly.

It is noted that, in other embodiments, when the base material 12 employs a solid state polymer, the base material 12 would be melted before putting into the mixing container 20, and the mixing container 20 keeps a temperature higher than a melting temperature of the base material 12 during the mixing process. The predetermined pressure can also be provided by other pressing devices or methods, for example, the predetermined pressure can be provided by a roller (not shown) cooperated the mixing container 20.

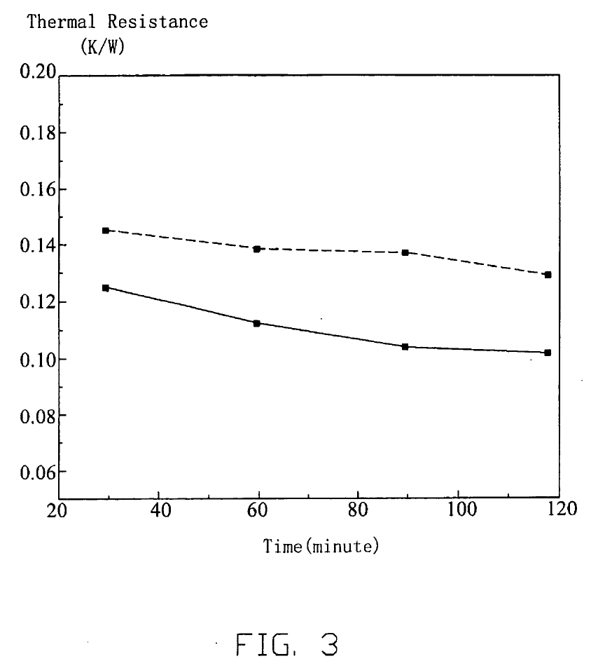

An ASTM-D5470 (ASTM, American Society for Testing and Materials) method is employed for measuring two thermal interface materials. One is the thermal interface material 10 in accordance with the preferred embodiment, the other is a typical thermal interface material provided by the following steps. Putting a mixture comprises 800 grams ZnO particles and the 200 grams polyester into a planetary mixer, and mixing the mixture by a mixing rotor at a speed of 20 RPM for 120 minutes, thereby forming the typical thermal interface material. During the measuring process, samples of the two thermal interface materials with different mixing time are measured, and a graph illustrating a relationship of thermal resistance and mixing time is formed by the results of the measure. Referring to FIG. 3, the broken line representing results of the typical thermal interface material, the real line representing results of the thermal interface material 10. FIG. 3 shows that the thermal conductivity of the thermal interface material 10 is much lower than that of the typical thermal interface material. That is to say, the thermal resistance of the thermal interface material can be reduced obviously by using the present method.

As stated above, the method for manufacturing the thermal interface material in accordance with a preferred embodiment applies a predetermined pressure during the mixing process. The internal pressure of the mixture is increased, which results the base material is apt to fill clearances between the particles, and accelerate dispersion of the particles, thereby the manufacturing speed and efficiency is improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method for manufacturing a thermal interface material comprising the steps of:
providing filling particles and a base material;
forming a mixture by putting the filling particles and the base material into a container, and keeping the base material melt or in liquid state; and
pressing a predetermined pressure to the mixture and mixing the mixture uniformly.

2. The method of claim 1, wherein the filling particles are selected from the group comprising silver, gold, copper, nickel, aluminum, aluminum oxide, zinc oxide, boron nitride, bauxite, aluminum nitride, graphite, black carbon, and a combination thereof.

3. The method of claim 1, wherein the base material employs a liquid state polymer selected from the group comprising silicone oil, polyethylene glycol, polyester, and a combination thereof

4. The method of claim 1, wherein the base material employs a solid state polymer selected from the group comprising polyvinyl acetate, polythene, siloxane, polyvinyl chloride, amino epoxide resin, polyacrylate, polypropylene, epoxide resin, polyformaldehyde, polyacetal, polyvinyl alcohol, and a combination thereof.

5. The method of claim 4, wherein the method further comprising melting the base material before putting into the container.

6. The method of claim 1, wherein the ratio by weight of the filling particles to the base material is 1:1 to 9:1.

7. The method of claim 1, wherein the predetermined pressure is in the range from 10⁴ newton/m² to 10⁶ newton/m².

8. The method of claim 1, wherein the predetermined pressure is provided by a pressure plunge.

9. The method of claim 1, wherein the predetermined pressure is provided by increasing the air pressure inside the container.

10. The method of claim 1, wherein the mixture is mixed by a mixing rotor.

11. The method of claim 10, wherein the speed of the mixing rotor is in the range from 5 RPM to 100 RPM.

12. The method of claim 1, wherein the time of the mixing step is in the range from 30 minutes to 24 hours.

13. A method for manufacturing a thermal interface material comprising the steps of
providing a container;
putting filling particles into a base material received in the container, the base material being melted or in liquid state;
mixing the filling particles with the base material under a predetermined pressure.

14. The method of claim 1, wherein the filling particles are selected from the group comprising silver, gold, copper, nickel, aluminum, aluminum oxide, zinc oxide, boron nitride, bauxite, aluminum nitride, graphite, black carbon, and a combination thereof.

15. The method of claim 1, wherein the base material employs a liquid state polymer selected from the group comprising silicone oil, polyethylene glycol, polyester, and a combination thereof.

16. The method of claim 1, wherein the base material employs a solid state polymer selected from the group comprising polyvinyl acetate, polythene, siloxane, polyvinyl chloride, amino epoxide resin, polyacrylate, polypropylene, epoxide resin, polyformaldehyde, polyacetal, polyvinyl alcohol, and a combination thereof.

17. The method of claim 4, wherein the method further comprising melting the base material before putting into the container.

18. The method of claim 1, wherein the ratio by weight of the filling particles to the base material is 1:1 to 9:1.

19. The method of claim 1, wherein the predetermined pressure is in the range from 10⁴ newton/m² to 10⁶ newton/m².

20. A method for manufacturing a thermal interface material comprising the steps of:
providing filling particles and a base material;
melting the base material;
forming a mixture by putting the filling particles and the base material into a container, and keeping the base material in liquid state; and
pressing a predetermined pressure to the mixture and mixing the mixture uniformly.
